(19) United States
(12) Patent Application Publication
(10) Pub. No.: US 2019/0006559 A1
(43) Pub. Date: Jan. 3, 2019

(54) MICRO LIGHT EMITTING DIODE AND DISPLAY PANEL

(71) Applicant: PlayNitride Inc., Tainan City (TW)

(72) Inventors: Yu-Hung Lai, Tainan City (TW); Yu-Yun Lo, Tainan City (TW); Tzu-Yang Lin, Tainan City (TW)

(73) Assignee: PlayNitride Inc., Tainan City (TW)

(21) Appl. No.: 16/019,556

(22) Filed: Jun. 27, 2018

(30) Foreign Application Priority Data
Jun. 30, 2017 (TW) 106121884

(51) Int. Cl. H01L 33/38; H01L 25/075; H01L 27/12; H01L 33/44; H01L 33/62; H01L 33/32; H01L 33/06

(52) U.S. Cl. CPC H01L 33/38; H01L 25/0753; H01L 27/1214; H01L 33/06; H01L 33/62; H01L 33/32; H01L 33/44

(57) ABSTRACT

A micro light emitting diode including an epitaxial layer, an insulation layer, a first electrode, and a second electrode is provided. The insulation layer is located on a surface of the epitaxial layer and has a first through hole and a second through hole. The first electrode is electrically connected to a first-type semiconductor layer of the epitaxial layer through the first through hole and has a plurality of first-electrode flat portions. The first-electrode flat portions respectively have different horizontal heights relative to the epitaxial layer. The second electrode is electrically connected to a second-type semiconductor layer of the epitaxial layer through the second through hole and has a plurality of second-electrode flat portions. The second-electrode flat portions respectively have different horizontal heights relative to the epitaxial layer. A display panel is also provided.

### CROSS-REFERENCE TO RELATED APPLICATION

This application claims the priority benefit of Taiwan application serial no. 106121884, filed on Jun. 30, 2017. The entirety of the above-mentioned patent application is hereby incorporated by reference herein and made a part of this specification.

### BACKGROUND OF THE INVENTION

### Field of the Invention

The invention relates to a light emitting diode and a display panel; particularly, the invention relates to a micro light emitting diode (micro LED, μLED) and a display panel having the μLED.

### Description of Related Art

The μLED is characterized by self-luminescent display. Compared to the organic light emitting diode (OLED), which is also self-luminous, the μLED has higher efficiency, longer life, and is made of a rather stable material that is not easily affected by the environment. Therefore, the μLED is expected to surpass the OLED and become the mainstream display in the future.

However, because of the small size of the μLED, the μLED may encounter a number of technical issues during the bonding process. For instance, the μLED is smaller than the normal light emitting diode, the distance between two electrodes of the μLED is shorter. In the bonding process, the bonding pads on the substrate and the electrodes on the μLED need to be slightly heated, and the μLED is required to be pressed down toward the bonding pad to complete the bonding process. However, after the electrodes are heated and pressed, the heated and pressed electrode (120 or 130) is likely to extend, the adjacent electrodes are more likely to be in electrically connect with each other. The product yield of the μLED display panel thereby decreases. Besides, such a μLED display panel may encounter the issue of defect pixels, which results in the poor image quality of the display panels.

### SUMMARY OF THE INVENTION

The invention provides a micro LED that increases the bonding yield of a display panel using the μLED and allows the display panel using the μLED to have good manufacturing yield and favorable image quality.

The invention provides a display panel having good manufacturing yield and favorable image quality.

An embodiment of the invention provides a μLED including an epitaxial layer, an insulation layer, a first electrode, and a second electrode. The epitaxial layer has a first-type semiconductor layer, a light emitting layer, and a second-type semiconductor layer. The light emitting layer is disposed between the first-type semiconductor layer and the second-type semiconductor layer. The insulation layer is located on a surface of the epitaxial layer and has a first through hole to expose the first-type semiconductor and a second through hole to expose the second-type semiconductor. The first electrode is electrically connected to the first-type semiconductor layer and is contacted with the first-type semiconductor layer through the first through hole. The first electrode has a plurality of first-electrode flat portions with different horizontal heights relative to the epitaxial layer respectively. The second electrode is electrically connected to the second-type semiconductor layer and is contacted with the second-type semiconductor layer through the second through hole. The second electrode has a plurality of second-electrode flat portions with different horizontal heights relative to the epitaxial layer respectively. The number of the first-electrode flat portions is more than the number of the plurality of second-electrode flat portions.

An embodiment of the invention provides a display panel including a backplane and a plurality of the abovementioned μLEDs. The backplane has a plurality of sub-pixels. Each of the μLEDs is located in one of the sub-pixels. The μLEDs are electrically connected to the backplane.

In an embodiment of the invention, the first electrode and the second electrode are located at the same side of the epitaxial layer.

In an embodiment of the invention, the first electrode further includes a plurality of first-electrode inclined portions. Two ends of each first-electrode inclined portion are respectively connected to two of the first-electrode flat portions. The second electrode further includes at least one second-electrode inclined portions. Two ends of the second-electrode inclined portion are respectively connected to two of the second-electrode flat portions.

In an embodiment of the invention, the epitaxial layer further includes a contact hole. The contact hole penetrates the second-type semiconductor layer and the light emitting layer and exposes the first-type semiconductor layer. The insulation layer extends into the contact hole and covers a surface of the light emitting layer and the second-type semiconductor layer.

In an embodiment of the invention, the first through hole is located in the contact hole.

In an embodiment of the invention, the first through hole of the insulation layer is located in the contact hole, and a distance from one side of the first through hole to the contact hole is not equal to a distance from the other side of the first through hole to the contact hole.

In an embodiment of the invention, a sum of a width of the contact hole and a width of the first through hole is equal to or greater than half of a width of the first electrode.

In an embodiment of the invention, a length of the epitaxial layer falls within a range from 3 μm to 100 μm.

In an embodiment of the invention, the display panel further includes a plurality of first-electrode bonding pads and a plurality of second-electrode bonding pads. The first-electrode bonding pads and the second-electrode bonding pads are disposed on the backplane. One of the first-electrode bonding pads and one of the second-electrode bonding pads are disposed in one sub-pixel region. The first electrode is electrically connected to the backplane through the first-electrode bonding pad, and the second electrode is electrically connected to the backplane through the second-electrode bonding pad.

In an embodiment of the invention, a gap between the first electrode and the second electrode is smaller than a gap between the first-electrode bonding pad and the second-electrode bonding pad.

Based on the above, because the electrodes of the μLED provided in the embodiments of the invention include the flat portions having different horizontal heights relative to the epitaxial layer, bent structure may thereby be formed in the electrodes. When the μLEDs are bonded to the backplane of the display panel, the design of the bent structure in the electrodes in the μLED provided in the embodiments of the invention may further disperse the bonding pressure and avoid the epitaxial layer from being cracked by the bonding pressure. So that the display panel described in the embodiments of the invention may have good manufacturing yield and better image quality.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A is a schematic partial top view of a display panel according to an embodiment of the invention.

FIG. 1B is a schematic enlarged view of the region A in FIG. 1A.

FIG. 2A is a schematic cross-sectional view along a sectional line I-I′ in FIG. 1A.

FIG. 2B is a schematic enlarged view of a μLED bonded to the backplane.

FIG. 2C is a schematic enlarged view of the first electrode, the second electrode, the insulation layer, and the epitaxial layer in FIG. 2B.

FIG. 3 is a schematic enlarged view of a μLED bonded to a backplane according to another embodiment of the invention.

### DESCRIPTION OF THE EMBODIMENTS

Some other embodiments of the invention are provided as follows. It should be noted that the reference numerals and part of the contents of the previous embodiment are used in the following embodiments, in which identical reference numerals indicate identical or similar components, and repeated description of the same technical contents is omitted. Please refer to the description of the previous embodiment for the omitted contents, which will not be repeated hereinafter.

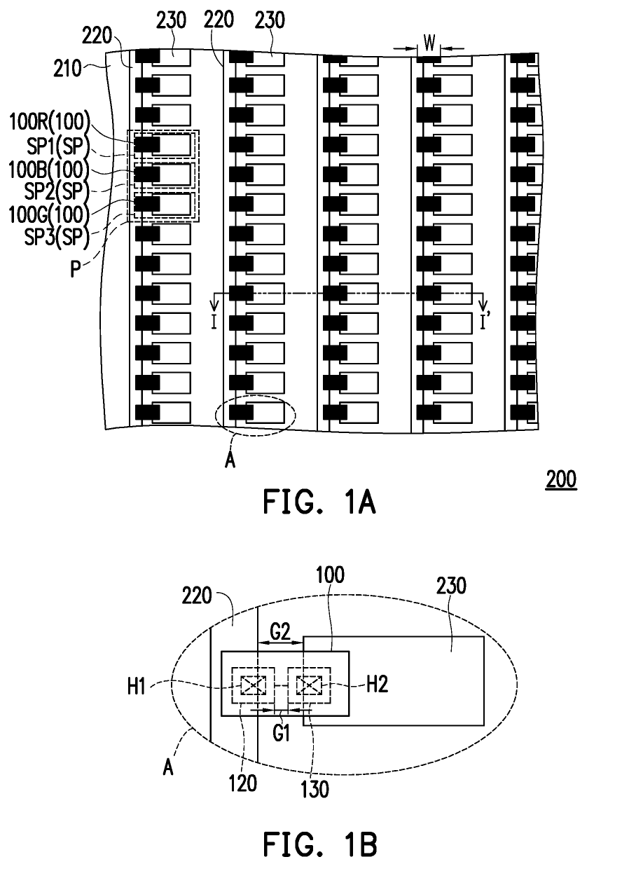

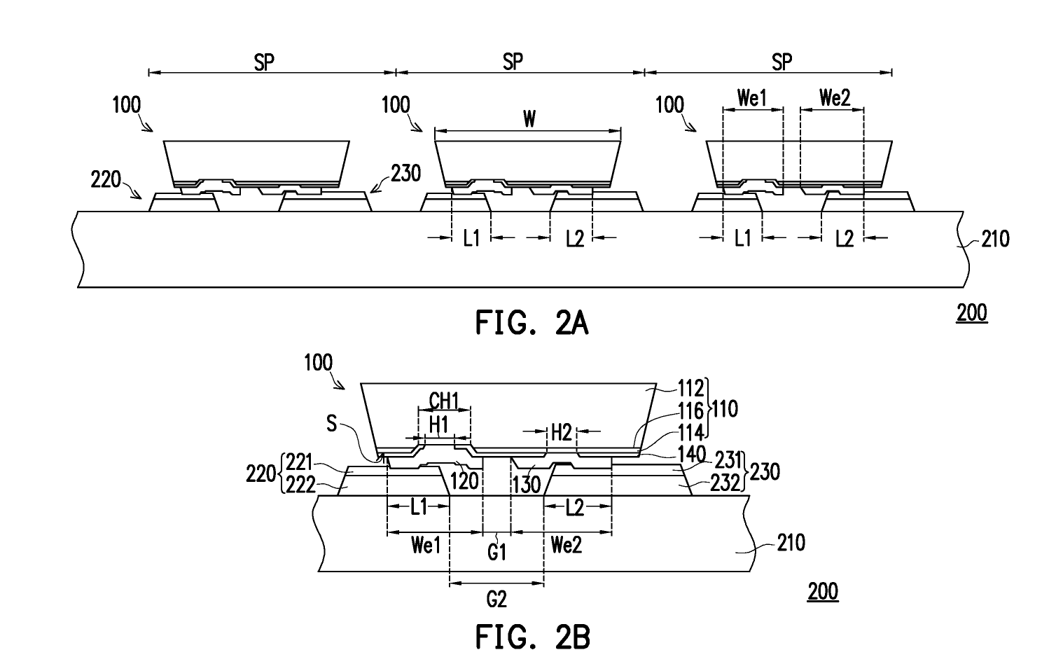

Please refer to FIG. 1A, FIG. 1B, and FIG. 2A which illustrate an embodiment of the invention. In this embodiment, a display panel 200 is a micro LED (μLED) display. The display panel 200 includes a backplane 210 and a plurality of micro light emitting diodes (μLEDs) 100. The backplane 210 has a plurality of sub-pixels SP, and the μLEDs 100 are located in the sub-pixels SP. With reference to FIG. 1A, in this embodiment, three sub-pixels SP1, SP2, and SP3 form a display pixel P. A red μLED 100R is disposed in the sub-pixel SP1, a blue μLED 100B is disposed in the sub-pixel SP2, and a green μLED 100G is disposed in the sub-pixel SP3, in other words, the μLEDs 100 includes the red μLEDs 100R, the blue μLEDs 100B and the green μLEDs 100G in this embodiment, but the invention is not limited thereto. The μLEDs 100 are electrically connected to the backplane 210. In detail, in this embodiment, the backplane 210 controls the brightness of the μLEDs 100 in each of the sub-pixels SP through a driving unit (not illustrated) in the backplane 210. The teachings, suggestions, and descriptions of a method for operating and implementing the display panel 200 can be derived from common knowledge of the related art and thus are not repeated herein.

The micro device (i.e. micro LED, μLED) described in the embodiments of the invention refers an electronic device having a size of 1 μm to 100 μm. In some embodiments, the maximum width of the micro device is 20 μm, 10 μm or 5 μm. In some embodiments, the maximum height of the micro device is smaller than 20 μm, 10 μm or 5 μm, the invention is not limited thereto. Some embodiments of the present invention may apply to a larger scale or a smaller scale. Although some embodiments of the invention specifically describe the μLED including a p-n junction diode, it should be noted that the invention is not limited thereto. In some embodiments of the present invention may apply to other micro semiconductor device such as a diode, a transistor, an integrated circuit or other micro semiconductor devices having photoelectric effect (such as Light-emitting diode (LED), laser diode (LD) or photo diode (PD).) Some embodiments of the invention may apply to a micro chip including circuits, for example, a logic chip or a memory chip using Si wafer or SOI (silicon on insulator) wafer as its materials or a microchip applying to RF (Radio Frequency) communication using GaAs wafer as its materials.

In this embodiment, the backplane 210 is a thin film transistor (TFT) substrate. In other embodiments, the backplane 210 may be a semiconductor substrate, a submount, a complementary metal-oxide-semiconductor (CMOS) circuit board, a liquid crystal on silicon (LCOS) substrate, or a substrate of other types, but the invention is not limited thereto.

Referring to FIG. 2A to FIG. 2C, in this embodiment, the μLED 100 includes an epitaxial layer 110, an insulation layer 140 located on the epitaxial layer 110, a first electrode 120, and a second electrode 130. The epitaxial layer 110 includes a first-type semiconductor layer 112, a second-type semiconductor layer 114, and a light emitting layer 116 located between the first-type semiconductor layer 112 and the second-type semiconductor layer 114. The length W of the epitaxial layer 110 falls within a range from 3 μm to 100 μm. To be more specific, the length W refers the maxium side length of a surface of the first-type semiconductor layer 112. The insulation layer 140 is located on a surface S of the epitaxial layer 110, and the surface S is a surface of the second-type semiconductor layer 114 facing the backplane 210 for example. The insulation layer 140 has a first through hole H1 and a second through hole H2. In detail, the insulation layer 140 is located on the second-type semiconductor layer 114. The first electrode 120 is disposed on the insulation layer 140 and is electrically connected to the first-type semiconductor layer 112 of the epitaxial layer 110 through the first through hole H1. The second electrode 130 is disposed on the insulation layer 140 and is electrically connected to the second-type semiconductor layer 114 of the epitaxial layer 110 through the second through hole H2. Referring to FIG. 2C, in this embodiment, the first electrode 120 has a plurality of first-electrode flat portions 122, and top surfaces of the first-electrode flat portions 122 respectively have different horizontal heights a, b, and c relative to the surface S (the surface of the second-type semiconductor layer 114 facing the backplane 210 according to this embodiment) of the epitaxial layer 110. The second electrode 130 has a plurality of second-electrode flat portions 132, and top surfaces of the second-electrode flat portions 132 respectively have different horizontal heights d and e relative to the surface S (the surface of the second-type semiconductor layer 114 facing the backplane 210 according to this embodiment) of the epitaxial layer 110.

The first electrode 120 further includes a plurality of first-electrode inclined portions 124. Each of the first-electrode inclined portions 124 is connected to two of the first-electrode flat portions 122. More specifically, the first electrode 120 has two first-electrode inclined portions 124 and three first-electrode flat portions 122 in this embodiment. The three first-electrode flat portions 122 respectively have different horizontal heights relative to the epitaxial layer 110 in cross-section view. The second electrode 130 further includes at least one second-electrode inclined portion 134. Two ends of the second-electrode inclined portion 134 are respectively connected to two of the second-electrode flat portions 132. The two second-electrode flat portions 132 respectively have different horizontal heights relative to the epitaxial layer 110 in cross-section view. More specifically, the second electrode 130 has two first-electrode inclined portions 124 and three first-electrode flat portions 122 in this embodiment. In this embodiment, the electrodes (the first electrode 120 and the second electrode 130) have the design of bent structure because of the flat portions (the first-electrode flat portions 122 and the second-electrode flat portions 132) and the inclined portions (the first-electrode inclined portions 124 and the second-electrode inclined portions 134), for example, but the invention is not limited thereto. Furthermore, the number of the first-electrode flat portions 122 is greater than the number of the second-electrode flat portions 132, and the number of the first-electrode inclined portions 124 is greater than the number of the second-electrode inclined portions 134. An inclination angle θ of the inclined portions falls within a range larger than 30 degrees and smaller than 90 degrees.

In view of the above, the electrodes of the μLED 100 respectively include the flat portions (i.e., the first-electrode flat portions 122 and the second-electrode flat portions 132) having different horizontal heights relative to the epitaxial layer 110, bent structure would be formed in the electrodes 120 and 130, and the μLED 100 provided in this embodiment is thus distinguished from the conventional μLED. As a result, when the μLEDs 100 are bonded to the backplane 210 of the display panel 200, the electrodes 120, 130 are heated and pressed to electrically connect the μLEDs 100 and the backplane 210, the electrode deformation will be improved to prevent short between adjacent electrodes. Moreover, owing to the design of the bent patterns in the electrodes 120 and 130, the bonding pressure may be further dispersed, so as to prevent cracks of the epitaxial layer 110 resulting from the bonding pressure. As such, the possibility of generating cracks and short circuits may be significantly decreased when the μLEDs 100 are bonded to the backplane 210 of the display panel 200, and the display panel 200 provided in this embodiment may have good manufacturing yield and good image quality.

Referring to FIG. 1A, FIG. 1B, FIG. 2A, and FIG. 2B, in this embodiment, the display panel 200 further includes a plurality of first-electrode bonding pads 220 and a plurality of second-electrode bonding pads 230, and the μLEDs 100 are bonded to the backplane 210 in a flip-chip manner. Specifically, the μLEDs 100 are bonded to the first-electrode bonding pads 220 through the first electrodes 120, and the μLEDs 100 are bonded to the second-electrode bonding pads 230 through the second electrodes 130. More specifically, in this embodiment, the first-electrode bonding pads 220 serve as parts of a common electrode circuit (not illustrated), and the second-electrode bonding pads 230 act as a driving electrode circuit (not illustrated) in the backplane 210 to receive a driving signal. Referring to FIG. 1B and FIG. 2B, a gap G1 between the first electrode 120 and the second electrode 130 of the μLEDs 100 is smaller than a gap G2 between the first-electrode bonding pad 220 and the second-electrode bonding pad 230 on the backplane 210. In addition, in this embodiment, an overlapping area between the first electrode 120 and the first-electrode bonding pads 220 is larger than 50% of an area of the first electrode 120, and an overlapping area between the second electrode 130 and the second-electrode bonding pads 230 is also larger than 50% of an area of the second electrode 130. In other words, as shown in the cross-sectional view of FIG. 2A, a width of the first electrode 120 is We1, and a width of the second electrode 130 is We2. A width L1 of an overlapping area of the projection of the first-electrode bonding pads 220 and the first electrode 120 on the backplane 210 is larger than ½*We1, and a width L2 of an overlapping area of the projection of the second-electrode bonding pads 230 and the second electrode 130 on the backplane 210 is larger than ½*We2. The process yield and the bonding stability of the display panel 200 provided in this embodiment may be effectively enhanced due to the above design.

Referring to FIG. 2A and FIG. 2B, it should be further mentioned that the first-electrode bonding pads 220 include a contact layer 221 and a conductive layer 222. The contact layer 221 is in contact with the first electrode 120 of the μLEDs 100 and is located between the first electrode 120 and the conductive layer 222. The contact layer 221 is configured to be bonded to the first electrode 120 and forms an ohmic contact. The conductive layer 222 transmits current. The second-electrode bonding pads 230 also include a contact layer 231 and a conductive layer 232. The contact layer 231 is in contact with the second electrode 130 of the μLEDs 100 and is located between the second electrode 130 and the conductive layer 232. The contact layer 231 is configured to be bonded to the second electrode 130 and forms an ohmic contact. The conductive layer 232 transmits current. In this embodiment, through the structure of the composite layer, the first-electrode bonding pads 220 and the second-electrode bonding pads 230 may be bonded the μLEDs 100 to the display panel 200 firmly and current can be well transmitted to the μLEDs 100. In this embodiment, the contact layers 221 and 231 are often made of an alloy material, such that the contact layers 221 and 231 may have favorable mechanical properties and antioxidant capacity. The conductive layers 222 and 232 are often made of a material with low impedance.

Referring to FIG. 1B and FIG. 2B to FIG. 2C, to be more specific, the epitaxial layer 110 of the μLED 100 has a contact hole CH1. The first through hole H1 is located in the contact hole CH1. The first through hole H1 of the insulation layer 140 is not located in the middle of the contact hole CH1, for example, the left side of the contact hole CH1. In other words, a distance from one side of the first through hole H1 to the contact hole CH1 is not equal to a distance from the other side of the first through hole H1 to the contact hole CH1. In other embodiments not illustrated in the drawings, the first through hole H1 is located in the middle of the contact hole CH1. The contact hole CH1 penetrates the second-type semiconductor layer 114 and the light emitting layer 116 and exposes the first-type semiconductor layer 112. The insulation layer 140 extends into the contact hole CH1 and covers the second-type semiconductor layer 114, the light emitting layer 116, and a portion of the first-type semiconductor layer 112. The first through hole H1 and the second through hole H2 respectively penetrate the insulation layer 140 and respectively expose the first-type semiconductor layer 112 and the second-type semiconductor layer 114. The first electrode 120 is in contact with the first-type semiconductor layer 112 through the contact hole CH1 and the first through hole H1, and the second electrode 130 is in contact with the second-type semiconductor layer 114 through the second through hole H2. The material of the insulation layer 140 is an inorganic insulation material or an organic insulation material, for example. In this embodiment, the material of the insulation layer 140 is silicon nitride and silicon dioxide, for example. The first-type semiconductor layer 112 is an n-type semiconductor layer made of n-type gallium nitride (n-GaN), for example. The first electrode 120 is an n-type electrode. The second-type semiconductor layer 114 is a p-type semiconductor layer made of p-type gallium nitride (p-GaN), for example. The second electrode 130 is a p-type electrode. The light emitting layer 116 has a multiple quantum well (MQW) structure, for example. The MQW structure includes a plurality of quantum wells and a plurality of quantum barriers disposed alternately and repeatedly. The material of the light emitting layer 116 includes multiple layers of indium gallium nitride (InGaN) and multiple layers of gallium nitride (GaN) stacked alternately, for example. By designing the proportions of indium and gallium in the light emitting layer 116, the light emitting layer 116 may emit lights with different ranges of wavelengths. It should be noted that the material of the light emitting layer 116 mentioned above are merely exemplary, and the material of the light emitting layer 116 provided in this embodiment of the invention is not limited to the combination of InGaN and GaN.

Moreover, in this embodiment, because the first electrode 120 is connected to the first-type semiconductor layer 112 through the second-type semiconductor layer 114 and the light emitting layer 116, the number of inclined portions (first-electrode inclined portions 124) of the first electrode 120 is greater than the number of inclined portions (second-electrode inclined portions 134) of the second electrode 130. In other words, two first-electrode inclined portions 124 are formed in the first electrode 120. As such, the first electrode 120 may have better bonding yield due to well alignment and smaller step height.

Referring to FIG. 2A to FIG. 2C, in this embodiment, an overlap width We1 and an overlap width We2 are approximately the same. Therefore, in this embodiment, when the μLEDs 100 are bonded to the backplane 210 of the display panel 200, the pressure on the epitaxial layer 110 is balanced, so that the possibility of generating cracks of the epitaxial layer 110 may be significantly decreased.

In this embodiment, the first through hole H1 and the second through hole H2 of the insulation layer 140 have similar sizes. Referring to FIG. 2C, a ratio (D1/D2) of a width D1 of the cross-section of the first through hole H1 to a width D2 of the cross-section of the second through hole H2 falls within a range of 1±0.2. The through holes H1 and H2 having similar sizes may allow a contact area of the first electrode 120 and the first-type semiconductor layer 112 to be close to a contact area of the second electrode 130 and the second-type semiconductor layer 114. The display panel 200 provided in this embodiment may have stabilize current density to the μLEDs 100 through the first electrode 120 and the second electrode 130, and show good image quality through the above design.

Moreover, in this embodiment, a sum of the width (or the diameter) D1 of the first through hole H1 and a width (or the diameter) D3 of the contact hole CH1 is equal or larger than half of the width We1 of the first electrode 120. Said design of the μLEDs 100 provided in this embodiment may lead to the improved transfer and bonding yield. In detail, the width D1 of the first through hole H1 of the insulation layer 140 falls within a range from 6 μm to 10 μm, for example, and the width D3 of the contact hole CH1 falls within a range from 10 μm to 20 μm, for example. The width We1 of the first electrode 120 falls within a range from 22 μm to 30 μm, for example.

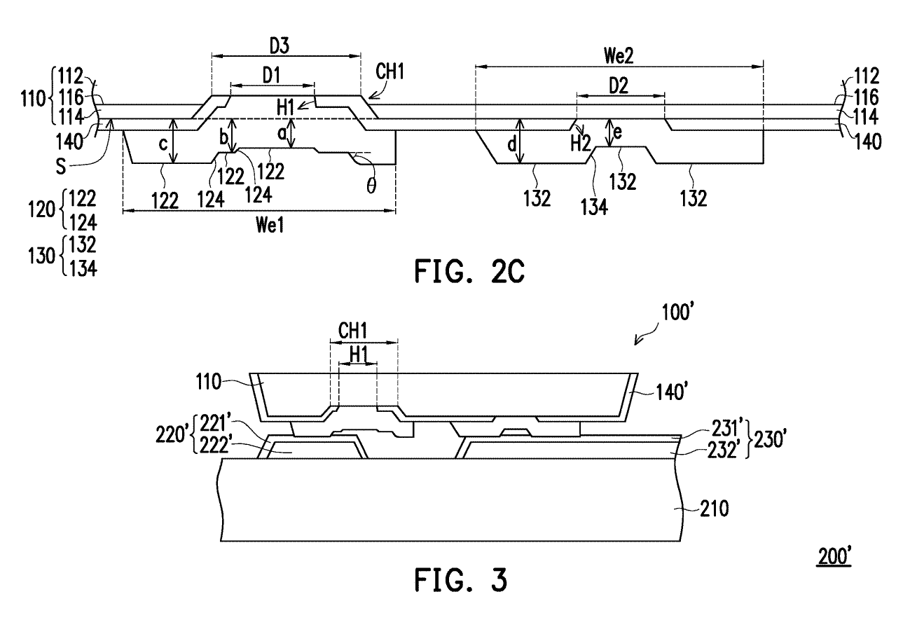

Please refer to FIG. 3 which illustrates a display panel 200′ according to another embodiment of the invention. This embodiment is different from the embodiments illustrated in FIG. 1A, FIG. 1B, and FIG. 2A to FIG. 2C because a contact layer 221′ of the first-electrode bonding pads 220′ on the backplane 210 covers a side surface of a conductive layer 222′, and a contact layer 231′ of the second-electrode bonding pads 230′ covers a side surface of a conductive layer 232′. In the display panel 200′ provided in this embodiment, the design of the contact layers 221′ and 231′ covering the conductive layers 222′ and 232′ may protect the conductive layers 222′ and 232′, and improve the reliability of the electric current transmission.

Besides, in the display panel 200′ provided in this embodiment, an insulation layer 140′ not only covers the surface of the epitaxial layer 110 facing the backplane 210 but also extends to be formed on a side surface of the epitaxial layer 110. The insulation layer 140′ may provide a better protection to the epitaxial layer 110 through the above design. The other components are generally the same as those provided in the first embodiment, and therefore the descriptions thereof are not repeated herein.

To sum up, the electrodes of the μLEDs of the display panel include the flat portions having different horizontal heights relative to the epitaxial layer, and thus bent structure may be formed in the electrodes through the above design. When the μLEDs are bonded to the backplane, the pressed and heated electrodes are less likely to extend toward the two sides of the electrodes. Moreover, through the design of the bent patterns in the electrodes, the μLED provided in the embodiments of the invention may further disperse the bonding pressure and avoid the epitaxial layer from being cracked by the bonding pressure. The defects quantity of μLED cracks and short circuits may be significantly decreased because the μLEDs have the electrode design of the bent structure, and thus the display panel provided in the embodiments of the invention has good manufacturing yield and good image quality.

The display panel in the embodiments of the invention may include other device such as a memory, a touch sensor and a battery, and the invention is not limited thereto. In other embodiments, the display panel may be a television, a tablet, a phone, a laptop computer, a monitor, an independent terminal server, a digital camera, a handheld game console, a media display, an E-paper display, a car display or an electronic bulletin board with large area.

Furthermore, since the size of the conventional LED is millimeter level, the size of the μLED in the embodiments of the invention is micron level, the micro LED display has advantages such as high resolution, low power consumption for display, energy saving, simple mechanism and thin thickness.

It will be apparent to those skilled in the art that various modifications and variations can be made to the disclosed embodiments without departing from the scope or spirit of this invention. In view of the foregoing, it is intended that the invention covers modifications and variations provided that they fall within the scope of the following claims and their equivalents.

What is claimed is:

1. A micro light emitting diode comprising:
an epitaxial layer having a first-type semiconductor layer, a light emitting layer, and a second-type semiconductor layer, wherein the light emitting layer is disposed between the first-type semiconductor layer and the second-type semiconductor layer;
an insulation layer located on a surface of the epitaxial layer and having a first through hole to expose the first-type semiconductor and a second through hole to expose the second-type semiconductor;
a first electrode electrically connected to the first-type semiconductor layer and contacted with the first-type semiconductor layer through the first through hole, wherein the first electrode has a plurality of first-electrode flat portions with different horizontal heights relative to the epitaxial layer respectively; and
a second electrode electrically connected to the second-type semiconductor layer and contacted with the second-type semiconductor layer through the second through hole, wherein the second electrode has a plurality of second-electrode flat portions with different horizontal heights relative to the epitaxial layer respectively, and the number of the first-electrode flat portions is more than the number of the plurality of second-electrode flat portions.

2. The micro light emitting diode according to claim 1, wherein the first electrode and the second electrode are located at the same side of the epitaxial layer.

3. The micro light emitting diode according to claim 1, wherein the first electrode further comprises a plurality of first-electrode inclined portions, two ends of each first-electrode inclined portion are respectively connected to two of the first-electrode flat portions, the second electrode further comprises at least one second-electrode inclined portion, and two ends of the second-electrode inclined portion are respectively connected to two of the second-electrode flat portions.

4. The micro light emitting diode according to claim 1, wherein the epitaxial layer further comprises a contact hole, the contact hole penetrates the second-type semiconductor layer and the light emitting layer and exposes the first-type semiconductor layer, and the insulation layer extends into the contact hole and covers a surface of the light emitting layer and the second-type semiconductor layer.

5. The micro light emitting diode according to claim 4, wherein the first through hole of the insulation layer is located in the contact hole.

6. The micro light emitting diode according to claim 4, wherein the first through hole of the insulation layer is located in the contact hole, and a distance from one side of the first through hole to the contact hole is not equal to a distance from the other side of the of the first through hole to the contact hole.

7. The micro light emitting diode according to claim 5, wherein a sum of a width of the contact hole and a width of the first through hole is equal to or greater than half of a width of the first electrode.

8. The micro light emitting diode according to claim 1, wherein a length of the epitaxial layer falls within a range from 3 μm to 100 μm.

9. A display panel comprising:
a backplane having a plurality of sub-pixels; and
a plurality of micro light emitting diodes, wherein each of the micro light emitting diodes is located in one of the sub-pixels, and each of the micro light emitting diodes comprises:
an epitaxial layer having a first-type semiconductor layer, a light emitting layer, and a second-type semiconductor layer, wherein the light emitting layer is located between the first-type semiconductor layer and the second-type semiconductor layer;
an insulation layer disposed on a surface of the epitaxial layer and having a first through hole to expose the first-type semiconductor and a second through hole to expose the second-type semiconductor;
a first electrode electrically connected to the first-type semiconductor layer and contacted with the first-type semiconductor layer through the first through hole, wherein the first electrode has a plurality of first-electrode flat portions with different horizontal heights relative to the epitaxial layer respectively; and
a second electrode electrically connected to the second-type semiconductor layer and contacted with the second-type semiconductor layer through the second through hole, wherein the second electrode has a plurality of second-electrode flat portions with different horizontal heights relative to the epitaxial layer respectively, and the number of the first-electrode flat portions is more than the number of the plurality of second-electrode flat portions,
wherein the plurality of micro light emitting diodes is electrically connected to the backplane.

10. The display panel according to claim 9, wherein the first electrode and the second electrode are located at the same side of the epitaxial layer.

11. The display panel according to claim 9, wherein the first electrode further comprises a plurality of first-electrode inclined portions, two ends of each first-electrode inclined portions are respectively connected to two of the first-electrode flat portions, the second electrode further comprises at least one second-electrode inclined portion, and two ends of the second-electrode inclined portion are respectively connected to two of the second-electrode flat portions.

12. The display panel according to claim 9, wherein the epitaxial layer further comprises a contact hole, the contact hole penetrates the second-type semiconductor layer and the light emitting layer and exposes the first-type semiconductor layer, and the insulation layer extends into the contact hole and covers a surface of the light emitting layer and the second-type semiconductor layer.

13. The display panel according to claim 12, wherein the first through hole is located in the contact hole.

14. The display panel according to claim 12, wherein the first through hole of the insulation layer is located in the contact hole, and a distance from one side of the first through hole to the contact hole is not equal to a distance from the other side of the first through hole to the contact hole.

15. The display panel according to claim 12, wherein a sum of a width of the contact hole and a width of the first through hole is equal to or greater than half of a width of the first electrode.

16. The display panel according to claim 9, wherein a length of the epitaxial layer falls within a range from 3 μm to 100 μm.

17. The display panel according to claim 9, further comprising:
a plurality of first-electrode bonding pads disposed on the backplane; and
a plurality of second-electrode bonding pads disposed on the backplane, wherein the of first-electrode bonding pad and the second-electrode bonding pad are disposed in the sub-pixels,
the first electrode is electrically connected to the backplane through the first-electrode bonding pad, and the second electrode is electrically connected to the backplane through the second-electrode bonding pad.

18. The display panel according to claim 17, wherein a gap between the first electrode and the second electrode is smaller than a gap between the first-electrode bonding pad and the second-electrode bonding pads.
